(19) United States
(12) Patent Application Publication
(10) Pub. No.: US 2022/0186377 A1
(43) Pub. Date: Jun. 16, 2022

(54) ELECTROLESS PLATING UNDERCOAT FILM

(71) Applicant: IDEMITSU KOSAN CO.,LTD., Tokyo (JP)

(72) Inventors: Satoshi HACHIYA, Chiba (JP); Fumioki FUKATSU, Chiba (JP)

(73) Assignee: IDEMITSU KOSAN CO.,LTD., Tokyo (JP)

(21) Appl. No.: 17/442,372

(22) PCT Filed: Mar. 17, 2020
(86) PCT No.: PCT/JP2020/011806

§ 371 Date: Sep. 23, 2021

(30) Foreign Application Priority Data
Mar. 27, 2019 (JP) 2019-060943

(51) Int. Cl. C23C 18/16; C23C 18/42; C23C 18/38; C23C 18/20

(52) U.S. Cl. CPC C23C 18/1641; C23C 18/2053; C23C 18/38; C23C 18/42

(57) ABSTRACT

An electroless plating undercoat film comprising (A) a conductive polymer and further comprising (B) a reactant of a polyol resin having an acid value and a polyisocyanate compound, wherein the acid value is 0.1 mgKOH/g to 30 mgKOH/g.

### TECHNICAL FIELD

The invention relates to an electroless plating undercoat film, a composition for forming an electroless plating undercoat film, a plating laminate, and a method of manufacturing a plating laminate.

### BACKGROUND ART

Recently, the utilization of high-frequency electric signals has become active in a wide variety of fields including, for example, in-vehicle radar and next-generation mobile phones, etc., and circuit substrates suitable for transmission of high-frequency electric signals is required.

As a conventional circuit substrate, for example, a material in which a base material and a metal layer (copper foil or the like) are bonded together by an adhesive is used as disclosed in Patent Document 1.

On the other hand, as disclosed in Patent Documents 2 and 3, a technique of forming an undercoat film for electroless plating on a base material and applying electroless plating thereto is known.

### RELATED ART DOCUMENTS

### Patent Documents

[Patent Document 1] JP H5-226831

[Patent Document 2] JP 2017-197848

[Patent Document 3] WO 201 9/013179

### SUMMARY OF THE INVENTION

In the technique disclosed in Patent Document 1, the surface of copper foil on the base material side is roughened in order to secure the adhesiveness between the base material and copper foil. As a result, attenuation in transmitting a high-frequency signal is particularly remarkable. If the smoothness of the surface on the base material side of copper foil is to be increased, the adhesiveness between the base material and copper foil is impaired.

In the technique of Patent Document 2, conductive polymer fine particles are blended in an undercoat film for electroless plating, and a catalyst metal is adsorbed thereon to form a plating layer. In this case, since the adsorption point of the catalyst metal is limited, the adhesiveness tends to be lowered.

In the art of Patent Document 3, although the undercoat film formed using the composition for forming a plating undercoat film exhibits adhesiveness to both the base material and the electroless plating layer (metal layer), there has been found room for further improvement in view of better compatibility between adhesiveness and heat resistance.

It is an object of the invention to provide an electroless plating undercoat film, which are capable of better compatibility between adhesiveness and heat resistance, a composition for forming an electroless plating undercoat film, a plating laminate, and a method for manufacturing a plating laminate.

As a result of extensive studies, the inventors have found that an electroless plating undercoat film containing (A) a conductive polymer and further containing (B) a reactant of a polyol resin having an acid value and a polyisocyanate compound exhibits good adhesiveness to both a base material and an electroless plating layer by having a specific acid value, and also has excellent heat resistance, thereby completing the invention.

According to the invention, the following electroless plating undercoat film and the like are provided.

1. An electroless plating undercoat film comprising (A) a conductive polymer and further comprising (B) a reactant of a polyol resin having an acid value and a polyisocyanate compound, wherein the acid value is 0.1 mgKOH/g to 30 mgKOH/g.
2. The electroless plating undercoat film according to 1, wherein the component (B) comprises a polyester polyol resin having an acid value.
3. The electroless plating undercoat film according to 1 or 2, wherein the component (A) is a substituted or unsubstituted polyaniline.
4. The electroless plating undercoat film according to any one of 1 to 3, wherein the component (A) is a polyaniline complex in which a substituted or unsubstituted polyaniline is doped with a dopant.
5. The electroless plating undercoat film according to 4, wherein the dopant is an organic acid ion derived from sulfosuccinic acid derivative represented by the following formula (III):

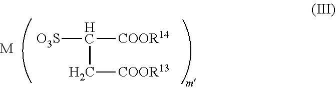

wherein in the formula (III), M is a hydrogen atom, an organic free radical, or an inorganic free radical; m′ is the valence of M; R¹³ and R¹⁴ are independently a hydrocarbon group or a —(R¹⁵O)ᵣ—R¹⁶) group; R¹⁵'s are independently a hydrocarbon group or a silylene group, R¹⁶ is a hydrogen atom, hydrocarbon group, or a R¹⁷₃Si— group, and r is an integer of 1 or more; R¹⁷'s are independently a hydrocarbon group.

6. The electroless plating undercoat film according to 4 or 5, wherein the dopant is sodium di-2-ethylhexyl sulfosuccinate.
7. A composition for forming an electroless plating undercoat film for forming the electroless plating undercoat film according to any one of 1 to 6 comprising:

(A) a conductive polymer,

(C) a polyol resin having an acid value, and

(D) a polyisocyanate compound.

8. The composition for forming an electroless plating undercoat film according to 7, wherein the total ratio of the component (C) and the component (D) to non-volatile components in the composition for forming an electroless plating undercoat film is 10 to 90% by mass.
9. The composition for forming an electroless plating undercoat film according to 7 or 8, wherein the molar ratio of the isocyanate group in the component (D) to the hydroxyl group in the component (C) is 0.6 to 10.
10. The composition for forming an electroless plating undercoat film according to any one of 7 to 9, further comprising (E) a polyol resin having no acid value.
11. The composition for forming an electroless plating undercoat film according to 10, wherein the component (E) comprises one or more selected from the group consisting of a polyester polyol resin having no acid value and a polyether polyol resin having no acid value.
12. The composition for forming an electroless plating undercoat film according to 10 or 11, wherein the total ratio of the component (C), the component (D), and the component (E) to non-volatile components in the composition for forming an electroless plating undercoat film is 10 to 90% by mass.
13. The composition for forming an electroless plating undercoat film according to any one of 10 to 12, wherein the molar ratio of the isocyanate group in the component (D) to the sum of the hydroxyl group in the component (C) and the hydroxyl group in the component (E) is 0.6 to 10.
14. The composition for forming an electroless plating undercoat film according to any one of 7 to 13, wherein the component (D) is a blocked polyisocyanate compound.
15. The composition for forming an electroless plating undercoat film according to any one of 7 to 14, further comprising a solvent.
16. A plating laminate comprising a substrate,

the electroless plating undercoat film according to any one of 1 to 6, and

an electroless plating layer comprising a metal,

wherein the electroless plating layer and the electroless plating undercoat film is in contact with each other.

17. The plating laminate according to 16, wherein the metal is copper.
18. The plating laminate according to 16 or 17, wherein the substrate is composed of a resin.
19. The plating laminate according to 18, wherein the substrate is composed of a polycarbonate resin, a polyester resin, a polyimide resin, a syndiotactic polystyrene resin, a liquid crystal polymer resin, or a polyphenylene sulfide resin.
20. A method of manufacturing a plating laminate comprising a step of: (i) forming an electroless plating undercoat film on a base material using the composition for forming an electroless plating undercoat film according to any one of 7 to 15, and

(ii) forming an electroless plating layer comprising a metal on the electroless plating undercoat film.

21. The method for manufacturing a plating laminate according to 20, wherein in the step (ii), palladium is supported on the electroless plating undercoat film, and the electroless plating undercoat film supporting palladium is contacted with an electroless plating solution to form the electroless plating layer.
22. The method of manufacturing a plating laminate according to 21, wherein the supporting of palladium on the electroless plating undercoat film is performed by bringing a palladium chloride solution into contact with the electroless plating undercoat film.
23. The method for manufacturing a plating laminate according to 21 or 22, wherein the electroless plating solution comprises one or more metals selected from the group consisting of copper, nickel, gold, palladium, silver, tin, cobalt, and platinum.

According to the invention, an electroless plating undercoat film, a composition for forming an electroless plating undercoat film, a plating laminate, and a method for manufacturing a plating laminate, which are capable of satisfactorily achieving both adhesion and heat resistance can be provided.

### BRIEF DESCRIPTION OF THE DRAWINGS

FIG. 1 is a schematic diagram showing a layer configuration of a plating laminate according to one embodiment of the invention.

### MODE FOR CARRYING OUT THE INVENTION Hereinafter, an electroless plating undercoat film and the like according to one embodiment will be described.

In this specification, “x to y” represents a numerical range of “x or more and y or less.”

In addition, when the term “(X) component” is used, for example, even when a commercially available reagent is used, it is intended to refer only to the compound which corresponds to the component (X) in the reagent, and does not include other components (solvents, etc.) in the reagent.

Further, the preferred provisions can be arbitrarily adopted. That is, one preferred provision may be employed in combination with one or more other preferred provisions. Combinations of the preferred ones are more preferable.

[Electroless Plating Undercoat film]

The electroless plating undercoat film according to one embodiment of the invention contains (A) a conductive polymer and further comprising (B) a reactant of a polyol resin having an acid value and a polyisocyanate compound, wherein the acid value is 0.1 mgKOH/g to 30 mgKOH/g. The acid value referred to here is the number of mg of potassium hydroxide (KOH) required to neutralize the acidic component contained in 1 g of electroless plating undercoat film. The acid value of the electroless plating undercoat film is a value measured by the measurement method described in Examples.

Electroless plating is a method of plating metals with autocatalytic activity using a reducing agent without electrolysis. For example, electroless copper plating is a chemical process, in which copper ions in solution are reduced using a reducing agent such as formaldehyde to deposit a metal copper film, and the deposited metal copper acts as an autocatalyst to further metallize and deposit copper ions. Such a chemical process forms an electroless plating layer containing a plating metal. In one aspect, the electroless plating undercoat film is provided on the base material and can be used as the undercoat film of the electroless plating layer.

The electroless plating undercoat film according to one embodiment of the invention contains the component (A) and the component (B), and the acid value may be 0.1 mgKOH/g or more, 0.3 mgKOH/g or more, or 0.5 mgKOH/g or more, and may be 30 mgKOH/g or less, 20 mgKOH/g or less, or 15 mgKOH/g or less. As a result, the electroless plating undercoat film exhibits good adhesiveness to both the base material and the electroless plating layer, and has excellent heat resistance.

As a comparative, even when the electroless plating undercoat film contains the component (A) and the component (B), if the acid value is not 0.1 mgKOH/g to 30 mgKOH/g, adhesiveness and heat resistance cannot be favorably compatible. Both cases where the acid value is less than 0.1 mgKOH/g and cases where the acid value is more than 30 mgKOH/g result in poor adhesiveness.

The electroless plating undercoat film according to one embodiment of the invention also contributes to smoothing of the surface of the electroless plating layer on the base material side (electroless plating undercoat film side), and even if the surface is smooth, the adhesiveness between the electroless plating layer and the electroless plating undercoat film is excellent. Therefore, the electroless plating layer (metal layer) formed on the electroless plating undercoat film is suitably used, for example, as a circuit (wiring) or the like in the circuit substrate, and can prevent attenuation, especially when transmitting high-frequency signal. The excellent adhesiveness prevents the electroless plating layer from peeling off even when the base material is bent, for example, when the base material constituting a circuit board is composed of resin and has flexibility.

The film thickness of the electroless plating undercoat film is not particularly limited, and is, for example, 0.1 μm or more, 0.15 μm or more, or 0.2 μm or more. When the film thickness is 0.1 μm or more, the adhesiveness is further improved, and an electroless plating catalyst, for example, Pd metal, is easily uniformly supported on the electroless plating undercoat film, whereby the electroless plating is easily uniformly performed. The upper limit of the film thickness of the electroless plating undercoat film may be, for example, 100 μm or less, 20 μm or less, or 10 μm or less.

Hereinafter, the components contained in the electroless plating undercoat film according to one embodiment will be described.

### [Component (A): a Conductive Polymer]

Examples of (A) a conductive polymer include π-conjugated polymer. Examples of the π-conjugated polymer include polyaniline, polypyrrole, polythiophene, and the like. The π-conjugated polymer is preferably a π-conjugated polymer complex doped with a dopant. Examples of such complex include, for example, a polyaniline complex in which a substituted or unsubstituted polyaniline is doped with a dopant, a polypyrrole complex in which a substituted or unsubstituted polypyrrole is doped with a dopant, and polythiophene complex in which a substituted or unsubstituted polythiophene is doped with a dopant. Among these, a polyaniline complex in which a substituted or unsubstituted polyaniline is doped with a dopant is preferred.

The weight-average molecular weight (hereinafter, referred to as molecular weight) of the polyaniline is preferably 5,000 or more. The molecular weight is preferably 10,000 to 500,000, more preferably 20,000 to 300,000, and even more preferably 20,000 to 200,000. The weight-average molecular weight is the molecular weight of the polyaniline, not the molecular weight of the polyaniline complex.

The molecular weight distribution is preferably 1.5 or more and 10.0 or less. From the viewpoint of conductivity, a narrower molecular weight distribution is preferable, but from the viewpoint of solubility in a solvent, a wider molecular weight distribution may be preferable.

The molecular weight and the molecular weight distribution are measured in polystyrene equivalent by gel permeation chromatography (GPC).

Examples of the substituent of the substituted polyaniline include straight-chain or branched hydrocarbon groups such as a methyl group, an ethyl group, a hexyl group, and an octyl group; alkoxy groups such as a methoxy group or an ethoxy group; aryloxy groups such as a phenoxy group; halogenated hydrocarbon groups such as an trifluoromethyl group (-CF₃ group).

The polyaniline is preferably unsubstituted polyaniline from the viewpoint of versatility and economical efficiency.

The substituted or unsubstituted polyaniline is preferably a polyaniline obtained by polymerization in the presence of an acid containing no chlorine atom. An acid containing no chlorine atom is an acid consisting of atoms belonging, for example, to Groups 1 to 16 and 18. Specific examples include phosphoric acid. Examples of the polyaniline obtained by polymerization in the presence of an acid containing no chlorine atom include polyaniline obtained by polymerization in the presence of phosphoric acid.

The polyaniline obtained in the presence of an acid containing no chlorine atom can lower the chlorine content of the polyaniline complex.

Examples of the dopant of the polyaniline complex include, for example, Bronsted acid ions arising from Bronsted acid or a salt of Bronsted acid, preferably organic acid ions arising from organic acids or salts of organic acids, and more preferably organic acid ions arising from compound represented by the following formula (I) (proton donor).

In the invention, when the dopant is expressed as a specific acid and when the dopant is expressed as a specific salt, each of them is assumed to be doped with a specific acid ion arising from a specific acid or a specific salt into the above-mentioned π-conjugate polymer.

M(XARₙ)ₘ (I)

M in the formula (I) is a hydrogen atom, an organic free radical, or an inorganic free radical.

Examples of the organic free radical include a pyridinium group, an imidazolium group, and an anilinium group, and the like. Examples of the inorganic free radical include lithium, sodium, potassium, cesium, ammonium, calcium, magnesium, iron, and the like.

X in the formula (I) is an anionic group, for example, —SO₃⁻ group, —PO₃²⁻ group, —PO₂(OH)⁻ group, —OPO₃²⁻ group, —OPO₂(OH)⁻ group, —COO⁻ group, and the like, and is preferably −SO₃⁻ group.

A in the formula (I) is a substituted or unsubstituted hydrocarbon group (including, for example, 1 to 20 carbon atoms).

The hydrocarbon group is a open-chain or cyclic saturated aliphatic hydrocarbon group, an open-chain or cyclic unsaturated aliphatic hydrocarbon group, or an aromatic hydrocarbon group.

Examples of the open-chain saturated aliphatic hydrocarbon group include a straight-chain or branched alkyl group (including, for example, 1 to 20 carbon atoms). Examples of the cyclic saturated aliphatic hydrocarbon group include cycloalkyl groups (including, for example, 3 to 20 carbon atoms) such as a cyclopentyl group, a cyclohexyl group, a cycloheptyl group, a cyclooctyl group, and the like. The cyclic saturated aliphatic hydrocarbon group may be a fusion of a plurality of cyclic saturated aliphatic hydrocarbon groups. Examples thereof include a norbornyl group, an adamantyl group, and a fused adamantyl group. Examples of the open-chain unsaturated aliphatic hydrocarbon group (including, for example, 2 to 20 carbon atoms) include a straight-chain or branched alkenyl group. Examples of the cyclic unsaturation aliphatic hydrocarbon group (including, for example, 3 to 20 carbon atoms) include a cyclic alkenyl group. Examples of the aromatic hydrocarbon group (including, for example, 6 to 20 carbon atoms) include a phenyl group, a naphthyl group, and an anthracenyl group.

When A is a substituted hydrocarbon group, the substituent is an alkyl group (including, for example, 1 to 20 carbon atoms), a cycloalkyl group (including, for example, 3 to 20 carbon atoms), a vinyl group, an allyl group, an aryl group (including, for example, 6 to 20 carbon atoms), an alkoxy group (including, for example, 1 to 20 carbon atoms), a halogen atom, a hydroxy group, an amino group, an imino group, a nitro group, a silyl group, or a group containing ester bond.

R in the formula (I) is bonded to A and is -H or a substituent represented by —R¹, —OR¹, —COR¹, —COOR¹, —(C═O)—(COR¹, or —(C═O)—(COOR¹), and R¹ is a hydrocarbon group which may have a substituent, a silyl group, a alkylsilyl group, a —(R²O)x-R³ group, or a —(OSiR³₂)x-OR³ group. R² is an alkylene group, R³ is a hydrocarbon group, and x is an integer of 1 or more. When x is 2 or more, each of the plurality of R²'s may be the same or different, and each of the plurality of R³'s may be the same or different.

Examples of the hydrocarbon group (including, for example, 1 to 20 carbon atoms) of R¹ include a methyl group, an ethyl group, a butyl group, a pentyl group, a hexyl group, a heptyl group, an octyl group, a nonyl group, a decyl group, a dodecyl group, a pentadecyl group, an eicosanil group, and the like. The hydrocarbon group may be straight-chain or may be branched.

The substituent of the hydrocarbon group is an alkyl group (including, for example, 1 to 20 carbon atoms), a cycloalkyl group (including, for example, 3 to 20 carbon atoms), a vinyl group, an allyl group, an aryl group (including, for example, 6 to 20 carbon atoms), an alkoxy group (including, for example, 1 to 20 carbon atoms), a halogen group, a hydroxy group, an amino group, an imino group, a nitro group, or a group containing ester bond. The hydrocarbon group of R³ is the same as that of R¹.

Examples of the alkylene group (including, for example, 1 to 20 carbon atoms) of R² include, for example, a methylene group, an ethylene group, a propylene group, and the like.

n in the formula (I) is an integer of 1 or more. When n is 2 or more, each of the plurality of R's may be the same or different.

m in the formula (I) is the valence of M/the valence of X.

As the compound represented by the formula (I), dialkylbenzenesulfonic acid, dialkylnaphthalenesulfonic acid, or a compound containing two or more ester bonds are preferred.

As the compound containing two or more ester bonds is more preferably sulfophthalic ester or a compound represented by the following formula (II):

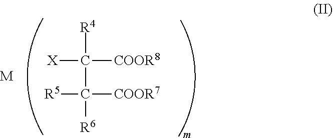

In the formula (II), M and X are the same as in the formula (I). X is preferably a —SO₃⁻ group.

R⁴, R⁵, and R⁶ are independently a hydrogen atom, a hydrocarbon group, or a R⁹3Si— group. Three R⁹'s are independently a hydrocarbon group.

Examples of the hydrocarbon group when R⁴, R⁵, and R⁶ are hydrocarbon groups include a straight-chain or branched alkyl group including 1 to 24 carbon atoms, an aryl group containing an aromatic ring (including, for example, 6 to 20 carbon atoms), an alkylaryl group (including, for example, 7 to 20 carbon atoms), and the like.

The hydrocarbon group of R⁹ is the same as that of R⁴, R⁵, and R⁶.

R⁷ and R⁸ in the formula (II) are independently a hyrdocarbon group or a —(R¹⁰O)_{q}—R¹¹ group. R¹⁰ is a hydrocarbon group or a silylene group, R¹¹ is a hydrogen atom, a hydrocarbon group, or R¹²₃Si—, and q is an integer of 1 or more. Three R¹²'s are independently a hydrocarbon group.

Examples of the hydrocarbon group when R⁷ and R⁸ are hydrocarbon groups include a straight-chain or branched alkyl group including 1 to 24, preferably 4 or more, carbon atoms, an aryl group containing a aromatic ring (including, for example, 6 to 20 carbon atoms), an alkylaryl group (including, for example, 7 to 20 carbon atoms), and the like, and specific examples thereof include, for example, a butyl group, a pentyl group, a hexyl group, an octyl group, a decyl group, and the like, all of which are straight-chain or branched.

Examples of the hydrocarbon group when R¹⁰ in R⁷ and R⁸ is a hydrocarbon group include, for example, a straight-chain or branched alkylene group including 1 to 24 carbon atoms, an arylene group containing an aromatic ring (including, for example, 6 to 20 carbon atoms), an alkylarylene group (including, for example, 7 to 20 carbon atoms), or an arylalkylene group (including, for example, 7 to 20 carbon atoms). In addition, examples of the hydrocarbon group when R¹¹ and R¹² in R⁷ and R⁸ are hydrocarbon groups are the same as that of R⁴, R⁵, and R⁶, and q is preferably 1 to 10.

Specific examples of the compound represented by formula (II) when R⁷ and R⁸ are —(R¹⁰O)_{q}—R¹¹ groups include two compounds represented by the following formulas.

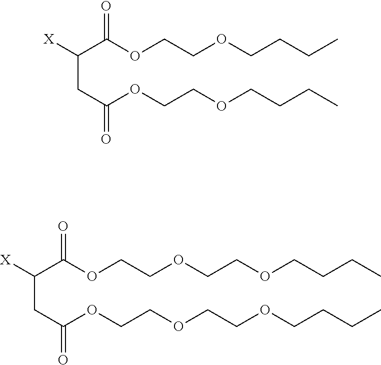

In the formulas, X is the same as in the formula (I).

It is further preferred that the compound represented by the formula (II) is a sulfosuccinic acid derivative represented by the following formula (III).

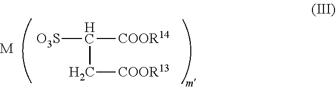

In the formula (III), M is the same as in the formula (I). m′ is the valence of M.

R¹³ and R¹⁴ are independently a hydrocarbon group or a —(R¹⁵O)ᵣ—R¹⁶) group. R¹⁵ is a hydrocarbon group or a silylene group, R¹⁶ is a hydrogen atom, hydrocarbon group, or a R¹⁷₃Si— group, and r is an integer of 1 or more. Three R¹⁷'s are independently a hydrocarbon group. When r is 2 or more, each of the plurality of R¹⁵'s may be the same or different.

The hydrocarbon group when R¹³ and R¹⁴ are hydrocarbon groups are the same as in R⁷ and R⁸.

The hydrocarbon group when R¹⁵ is a hydrocarbon group in R¹³ and R¹⁴ is the same as in R¹⁰. In addition, the hydrocarbon group when R¹⁶ and R¹⁷ are hydrocarbon groups in R¹³ and R¹⁴ is the same as in R⁴, R⁵, and R⁶.

r is preferably 1 to 10.

Specific examples of the case when R¹³ and R¹⁴ are —(R¹⁵O)ᵣ—R¹⁶ groups is the same as —(R¹⁰O)_{q}—R¹¹) in R⁷ and R⁸.

The hydrocarbon group of R¹³ and R¹⁴ is the same as in R⁷ and R⁸, and is preferably a butyl group, a hexyl group, a 2-ethylhexyl group, and decyl group.

As the compound represented by the formula (I), di-2-ethylhexylsulfosuccinic acid and sodium di-2-ethyl hexylsulfosuccinate (Aerosol OT) are preferred.

The doping of the dopant of the polyaniline complex into substituted or unsubstituted polyaniline can be confirmed by ultraviolet/visible/near-infrared spectroscopy or X-ray photoelectron spectroscopy, and the dopant can be used without any particular chemical structural limitation as long as the dopant has enough acidity to generate carriers in the polyaniline.

The doping ratio of the dopant to the polyaniline is preferably 0.35 or more and 0.65 or less, more preferably 0.42 or more and 0.60 or less, still more preferably 0.43 or more and 0.57 or less, and particularly preferably 0.44 or more and 0.55 or less.

The doping ratio is defined as (number of moles of the dopant doped into polyaniline)/(number of moles of monomer unit of polyaniline). For example, a doping ratio of 0.5 for a polyaniline complex containing unsubstituted polyaniline and a dopant means that one dopant is doped with respect to two monomer unit moleculars of polyaniline.

The doping ratio can be calculated if the number of moles of the monomer unit of the dopant and polyaniline in the polyaniline complex can be measured. For example, when the dopant is an organic sulfonic acid, the number of moles of the sulfur atom derived from the dopant and the number of moles of the nitrogen atom derived from the monomer unit of polyaniline are quantified by an organic elemental analysis method, and the ratio of these values can be determined to calculate the doping ratio. In this regard, the method of calculating the doping ratio is not limited to this means.

The polyaniline complex may further contain phosphorus or may not contain phosphorus.

When the polyaniline complex contains phosphorus, the content of phosphorus is, for example, 10 ppm by mass or more and 5000 ppm by mass or less.

The content of phosphorus can be measured by ICP emission spectrometry.

Further, it is preferable that the polyaniline complex does not contain a Group 12 element (e.g., zinc) as an impurity.

The polyaniline complex can be produced in a well-known production method. For example, the polyaniline complex can be produced by chemical oxidative polymerization of substituted or unsubstituted aniline in a solution containing a proton donor, phosphoric acid, and an emulsifier different from the proton donor and having two liquid phases. The polyaniline complex can be produced by adding an oxidative polymerization agent into a solution containing substituted or unsubstituted aniline, a proton donor, phosphoric acid, and an emulsifier different from the proton donor, and having two liquid phases.

Here, “a solution having two liquid phases” means a state in which two liquid phases that are not compatible are present in the solution. For example, a state in which “a phase of a high polarity solvent” and “a phase of a low polarity solvent” are present in the solution is meant.

In addition, “a solution having two liquid phases” also includes a state in which one liquid phase is a continuous phase and the other liquid phase is a dispersed phase. Examples thereof include a state in which “a phase of a high polarity solvent” is a continuous phase and “a phase of a low polarity solvent” is a dispersed phase, and a state in which “a phase of a low polarity solvent” is a continuous phase and “a phase of a high polarity solvent” is a dispersed phase.

As a highly polar solvent used in the above method for producing a polyaniline complex, water is preferred, and as a low polarity solvent, for example, aromatic hydrocarbons such as toluene and xylene are preferred.

The proton donor is preferably a compound represented by the formula (I).

As the emulsifier, both ionic emulsifiers, in which the hydrophilic portion is ionic, and nonionic emulsifiers, in which the hydrophilic portion is nonionic, may be used, and one emulsifier may be used alone or two or more emulsifiers may be used in combination.

As an oxidizing agent used for chemical oxidative polymerization, peroxides, such as sodium persulfate, potassium persulfate, ammonium persulfate, and hydrogen peroxide; ammonium dichromate, ammonium perchlorate, potassium iron (III) sulfate, iron (III) trichloride, manganese dioxide, iodine acid, potassium permanganate, or iron pallatoluenesulfonate, and the like can be used, and persulfates such as ammonium persulfate are preferable.

These may be used alone or in combination of two or more thereof.

The molecular weight and the molecular weight distribution of polypyrrole, and a substituent of the substituted polypyrrole are the same as those of the above polyaniline.

There is no particular limitation on the dopant of the polypyrrole complex, and an acceptor dopant suitably used in a conductive polymer containing a polymer of pyrrole and/or pyrrole derivative can be appropriately used.

Typical examples thereof include sulfonic acids such as polystyrenesulfonic acid, paratoluenesulfonic acid, methanesulfonic acid, trifluoromethanesulfonic acid, anthraquinonesulfonic acid, benzenesulfonic acid, naphthalenesulfonic acid, sulfosalicylic acid, dodecylbenzenesulfonic acid, and allylsulfonic acid, halogens such as perchloric acid, chlorine, and bromine, Lewis acid, proton acid, and the like. These may be in acid form or in salt form. Preferred examples in terms of solubility in monomers include tetrabutylammonium perchlorate, tetraethylammonium perchlorate, tetrabutylammonium tetrafluoroborate, tetrabutylammonium trifluoromethanesulfonate, trifluorosulfonimidotetrabutylammonium, dodecylbenzenesulfonic acid, paratoluenesulfonic acid, and the like.

The amount of dopant used when using the dopant is preferably in the range of 0.01 to 0.3 molecules of dopant per unit of pyrrole polymer. An amount of less than 0.01 molecules is insufficient as the amount of dopant required to form a sufficiently conductive path, and it is difficult to obtain high conductivity. On the other hand, since the doping ratio is not improved even when more than 0.3 molecules are added, the addition of a dopant of more than 0.3 molecules is not preferable in terms of economics. Here, the unit of pyrrole polymer refers to a repeating portion corresponding to 1 moleculars of a monomer of a pyrrole polymer obtained by polymerizing a pyrrole monomer.

The molecular weight and the molecular weight distribution of polythiophene, and a substituent of the substituted polythiophene are the same as those of the above polyaniline. As the substituted polythiophene, polyethylenedioxythiophene (PEDOT) is preferred.

Examples of the dopant of the polythiophene complex include organic acid ions and inorganic acid ions of an anionic surfactant and the like. Examples of the organic acid ion of the anionic surfactant include sulfonic acid-based ions, esterified sulfate ions, and the like. Examples of the inorganic acid ion include a sulfate ion, halogen ions, nitrate ions, perchlorate acid ions, hexacyano iron acid ions, a phosphate ion, a phosphomolybdate ion, and the like.

### [Component (B): a Reactant of a Polyol Resin Having an Acid Value and a Polyisocyanate Compound]

The component (B) is a reactant of (C) a polyol resin having an acid value and (D) a polyisocyanate compound described below.

This reactant is a product produced by bonding the component (C) and the component (D). Such a bond may be formed by forming a urethane bond between the hydroxyl group contained in the component (C) and the isocyanate group contained in the component (D). In one aspect, such a reactant may be a crosslinked compound formed by crosslinking the component (C) with the component (D).

Such a reactant may have an acid value derived from the component (C). By the acid value of the reactant, the acid value of the electroless plating undercoat film can be adjusted.

### [Component (C): a Polyol Resin Having an Acid Value]

(C) a polyol resin having an acid value is a resin having an acid value and having two or more hydroxyl groups (—OH groups). Examples of the polyol resin having an acid value include a polyester polyol resin having an acid value, a polyether polyol resin having an acid value, and the like. The acid value of the polyol resin having an acid value may be, for example, 1.0 mgKOH/g or more, 2.0 mgKOH/g or more, or 3.0 mgKOH/g or more, and may be 200 mgKOH/g or less, 150 mgKOH/g or less, or 100 mgKOH/g or less. The acid value of the polyol resin is the mass (mg) of potassium hydroxide required to neutralize 1 g of the polyol resin.

The acid value can be imparted, for example, by introducing a carboxyl group or a sulfoxyl group into polymer constituting the polyol resin. For example, a method of introducing a carboxyl group into a polymer is not particularly limited, and for example, a method of copolymerizing a monomer having a carboxyl group as an additional monomer at the time of synthesizing (polymerizing) or after synthesizing (polymerizing) a polymer (e.g., a polyester polyol resin and a polyether polyol resin) exemplified below as a polyol resin can be used. The polyol resin having an acid value may be an alternating copolymer, a random copolymer, a blocked copolymer, or a graft copolymer or the like in which a monomer having a carboxyl group is copolymerized. The monomer having a carboxyl group is not particularly limited, and may be, for example, a monomer in which a carboxyl group is introduced into a monomer commonly used to constitute a polyol resin. The polyol resin having an acid value is also available as commercial products.

The polyester polyol resin is usually obtained by polymerizing a polyol and a polyvalent carboxylic acid.

Examples of the polyol include neopentyl glycol, ethylene glycol, diethylene glycol, propylene glycol, 1,6-hexanediol, 1,4-butanediol, 1,9-nonanediol, 1,10-decanediol, 3-methylpentanediol, 2,4-diethylpentanediol, tricyclodecanedimethanol, 1,4-cyclohexanedimethanol, 1,2-cyclohexanedimethanol, 1,3-cyclohexanedimethanol, cyclohexanediol, hydrogenated bisphenol A, trimethylolpropane, pentaerythritol, and the like.

Examples of the polyvalent carboxylic acid include malonic acid, phthalic acid, terephthalic acid, isophthalic acid, tetrahydrophthalic acid, methyltetrahydrophthalic acid, hexahydrophthalic acid, methylhexahydrophthalic acid, succinic acid, glutaric acid, hexachloroendomethylenetetrahydrophthalic acid, endomethylenetetrahydrophthalic acid, endomethylenehexahydrophthalic acid, adipic acid, sebacic acid, azelaic acid, dimeric acid, decandicarboxylic acid, cyclohexanedicarboxylic acid, trimellitic acid, pyromellitic acid, trimesic acid, cyclopentanedicarboxylic acid, and the like.

By imparting an acid value to such a polyester polyol resin, a polyester polyol resin having an acid value is obtained.

The weight-average molecular weight of the polyester polyol resin having an acid value is preferably 2,000 to 50,000. The weight-average molecular weight is determined by the GPC method.

The glass transition temperature (Tg) of the polyester polyol resin having an acid value is preferably 5 to 90° C. Tg is measured by DSC (Differential Scanning calorimetry) method.

The hydroxyl value of the polyester polyol resin having an acid value is preferably 2 mgKOH/g to 70 mgKOH/g. The hydroxyl value of the polyester polyol resin is the mass (mg) of potassium hydroxide required to react 1 g of the polyester polyol resin with acetic anhydride and neutralize acetic acid generated in the reaction.

As the polyether polyol resin, for example, polyethylene glycol, polypropylene glycol, polytetramethylene glycol, polyl-methylbutylene glycol, or the like can be used.

Also, a polyether polyol obtained by copolymerizing a monomer for synthesizing the above polyether polyol and a polyhydric alcohol such as glycerin, trimethylolpropane, pentaerythritol, sorbitol, or triethanolamine within a range not to be gelled can be used.

By imparting an acid value to such a polyether polyol resin, a polyether polyol resin having an acid value is obtained.

The weight-average molecular weight of the polyether polyol resin having an acid value is preferably 400 to 10,000.

The hydroxyl value of the polyether polyol resin having an acid value is preferably 20 mgKOH/g to 500 mgKOH/g.

The method for measuring the weight-average molecular weight, the acid value, and the hydroxyl value of the polyether polyol resin having an acid value is the same as those described in the polyester polyol resin.

One or more kinds of polyol resins having an acid value can be used. For example, either one of a polyester polyol resin having an acid value and a polyether polyol resin having an acid value may be used alone, or both of them may be used in combination. For each resin, one kind of resin may be used alone, or two or more kinds of resins may be used in combination. In one aspect, it is preferable that the component (C) contain a polyester polyol resin having an acid value.

Note that, for example, polyvinyl acetal may be mentioned as the polyol resin, but the above-described polyester polyol resin and polyether polyol resin can further improve the heat resistance of the electroless plating undercoat film because decomposition due to heating is suppressed as compared with polyvinyl acetal. Accordingly, in one embodiment, the electroless plating undercoat film has a small content of polyvinyl acetal regardless of having an acid value or having no acid value, or does not contain polyvinyl acetal regardless of having an acid value or having no acid value.

### [Component (D): Polyisocyanate Compound]

The polyisocyanate compound is an compound having two or more isocyanate groups (—NCO groups), and may be a raw material of polyurethane in some cases.

When the component (C) is crosslinked by the component (D), the heat resistance of the electroless plating undercoat film is further improved.

The polyisocyanate is, for example, a compound represented by R′(—NCO)ₒ. In the formula, R′ is an aliphatic hydrocarbon (including, for example, 1 to 20 carbon atoms) such as methyl, ethyl, propyl, or butyl, or an aromatic hydrocarbon (including, for example, 6 to 20 carbon atoms) such as a benzene ring or a naphthalene ring, and o is an integer of 2 or more.

As a polyisocyanate compound, a blocked polyisocyanate compound is preferably used.

Usually, since the —NCO group is very reactive, the —NCO group is blocked into a blocked polyisocyanate so as to suppress and control its reactivity. A blocked polyisocyanate inhibits the reaction by blocking reactive groups such as a —NCO group in the system, and initiate the reaction by desorbing the blocking group by heating.

Specifically, examples of the polyisocyanate compound include HDI (hexamethylene diisocyanate)-based compound such as MF-K60B, MF-B60B, 17B-60P, TPA-100, TKA-100, P301-75E, 24A-100 manufactured by Asahi Kasei Corporation. In addition, D-550 and DB-980K manufactured by DIC Corporation, Coronate BI-301 and Coronate 2507 manufactured by Tosoh Corporation, and the like are also mentioned.

The curing temperature of the polyisocyanate compound is preferably 80° C. or higher, more preferably 90 to 180° C. When the curing temperature of polyisocyanate is in the above range, the heat resistance of the plating undercoat film can be improved.

In the case of blocked polyisocyanate, the above curing temperature is a temperature at which a blocking group is desorbed.

### [Component (E): a Polyol Resin Having no Acid Value]

In one aspect, the component (B) is a reactant of the component (C) and the component (E) and the component (D). Here, the component (E) is a polyol resin having no acid value.

In this specification, “polyol resin having no acid value” means a polyol resin having an acid value of less than 1.0 mgKOH/g. In one aspect, the acid value of the polyol resin having no acid value may be 0.5 mgKOH/g or less, 0.1 mgKOH/g or less, 0.05 mgKOH/g or less, or 0 mgKOH/g.

By using the component (C) and the component (E) in combination as the polyol resin, the acid value of the electroless plating undercoat film can be adjusted with high accuracy by adjusting the blending ratio of both components.

In this aspect, the reactant may be a crosslinked compound in which both the component (C) and the component (E) are crosslinked by the component (D).

As the component (E), a polyol resin having no acid value among a polyol resin having an acid value described as the component (C) (e.g., a polyester polyol resin having an acid value and a polyether polyol resin having an acid value), specifically, a polyol resin having an acid value of less than 1.0 mgKOH/g can be used.

As the component (E), one or more selected from the polyol resin having an acid value of less than 1.0 mgKOH/g exemplified above can be used.

In another embodiment, by using two or more kinds of polyol resins having different acid values as the component (C) in combination, the acid value of the electroless plating undercoat film can be adjusted by adjusting the blending ratio of both polyol resins.

### [Urethane Resin]

The electroless plating undercoat film may further include a urethane resin. As the urethane resin, for example, those obtained by reacting a polyisocyanate with a polyol and the like can be used.

Any known compounds can be used without particular limitation, as long as the compound has at least two or more isocyanate groups.

Specific examples include, for example, aromatic isocyanates such as TDI (tolylene diisocyanate)-based, MDI (diphenylmethane diisocyanate)-based, XDI (xylene diisocyanate)-based, NDI (naphthylene 1,5-diisocyanate)-based, and TMXDI (tetramethylene xylylene diisocyanate)-based, alicyclic isocyanates such as IPDI (isophorone diisocyanate)-based, H12MDI (hydrogenated MDI, dicyclohexylmethane diisocyanate)-based, and H6XDI (hydrogenated XDI)-based, aliphatic isocyanates such as HDI (hexamethylene diisocyanate)-based, DDI (dimeric acid diisocyanate)-based and NBDI (norbornene diisocyanate)-based. One kind of these may be used alone, or two or more kinds of these may be used in combination.

Examples of the polyol include polyether polyols such as polyoxyethylene glycol, polyoxypropylene glycol, and polyoxytetramethylene glycol; polyester polyols such as polyethylene adipate, polyethylene-butylene adipate, and polycaprolactone; acrylic polyols; polycarbonate-based polyols; polydimethylsiloxane-ethylene oxide adduct; polydimethylsiloxane-propylene oxide adduct; castor oil; and the like. One kind of these may be used alone, or two or more kinds of these may be used in combination.

The urethane resin is soft and stretchable, and can prevent the undercoat film from becoming too brittle due to the crosslinked structure.

Specific examples of the urethane resin include MAU series such as MAU1008, MAU4308HV, MAU5022, and MAU9022 (manufactured by Dainichiseika Color & Chemicals Mfg. Co., Ltd.); ASPU series such as ASPU360, ASPU112, ASPU116, and ASPU121 (manufactured by DIC Corporation); HYDRAN series such as HYDRAN AP-20, AP-30F, AP-40F, and WLS-213 (manufactured by DIC Corporation), UCOAT series such as UCOAT UX-150, UX-200, UX-310, and UWS-145 (Sanyo Chemical Industries, Ltd.), ACRYT series such as ACRYT WBR-2018, WBR-016U, and WEM-3008 (Taisei Fine Chemical Co., Ltd.); PTG-RSN (DIC Graphics Corporation); and the like.

MAU series can introduce a polar group such as an amino group and a carboxyl group, and can improve compatibility and adhesiveness with various binders. The presence of reactive groups enables the formation of flexible coated films even after curing.

ASPU series is a solvent system, and flexible and tough film can be produced by having reactive groups together with improved weather resistance, abrasion, and flexibility.

HYDRAN series is water system, and can be dissolved in various solvents to have performance equivalent to that of ASPU series.

ACRYT series is a urethane emulsion which does not have a reactive group, and can be used in waterborne coating.

The urethane resin usually has a structure represented by the following formula:

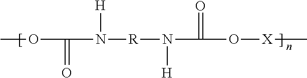

In the formula, R and X are independently a substituted or unsubstituted divalent hydrocarbon group, a substituted or unsubstituted divalent aromatic hydrocarbon group, or a divalent group which is obtained by bonding one or more substituted or unsubstituted divalent aromatic hydrocarbon groups with one or more substituted or unsubstituted divalent aliphatic hydrocarbon groups in an arbitrary order, which is derived from a monomer in synthesizing a urethane resin.

Examples of the divalent aromatic hydrocarbon group include a aromatic hydrocarbon group including 6 to 50 ring carbon atoms and the like. Specific examples thereof include a phenylene group and a naphthylene group.

Examples of the divalent aliphatic hydrocarbon group include a linear aliphatic group including 6 to 50 carbon atoms, a branched aliphatic hydrocarbon group including 6 to 50 carbon atoms, and the like. Specific examples thereof include a methylene group, a ethylene group, and a propylene group.

Examples of the divalent group which is obtained by bonding one or more divalent aromatic hydrocarbon groups with one or more divalent aliphatic hydrocarbon groups in an arbitrary order include a group in which a phenylene group and a methylene group are bonded with each other, a group in which a naphthylene group and an ethylene group are bonded with each other, and the like.

Examples of the substituent when the group has a substituent include a hydroxyl group, a carboxyl group, nitro group, cyano group, and an amino group.

One kind of urethane resins may be used alone, or two or more kinds of urethane resins may be used in combination.

### [Epoxy Resin and Epoxy Compound]

The electroless plating undercoat film may further contain one or more kinds selected from the group consisting of epoxy resins and epoxy compounds. The epoxy resins and the epoxy compounds may be contained in the electroless plating undercoat film in a cross-linked state.

The epoxy resin is a crosslinkable compound and can be subjected to a crosslinking reaction by an epoxy group in the resin and can be cured. The predetermined amount of epoxy resin imparts excellent heat resistance and adhesiveness to the electroless plating undercoat film.

Examples of the epoxy resin include phenolic epoxy resins, phenolic novolac epoxy resins, cresol novolac epoxy resins, dicyclopentadiene epoxy resins, bisphenol epoxy resins, naphthalene epoxy resins, and the like. Among them, dicyclopentadiene epoxy resins, bisphenol epoxy resins, and naphthalene epoxy resins are preferred.

Examples of the dicyclopentadiene epoxy resin include HP4710, HP7200HH, HP7200H, HP7200 manufactured by DIC Corporation. Further, examples of the naphthalene epoxy resin include HP4710 manufactured by DIC Corporation.

The glass transition temperature of the epoxy resin is preferably 60 to 110° C., more preferably 70 to 105° C., and still more preferably 75 to 100° C.

When a undercoat film is formed using a composition for forming an electroless plating undercoat film containing an epoxy resin, the glass transition temperature of the epoxy resin can be in the above range to improve the heat resistance and thermal-shock resistance of the undercoat film.

By coating a base material with a composition obtained by mixing an epoxy resin having the above-mentioned glass transition temperature with a conductive polymer such as a polyaniline complex to form a plating undercoat film, excellent adhesiveness to the base material and the plating coating film is exhibited in a heat resistance test and a thermal-shock resistance test after electroless plating. This is considered to be because, by adding an epoxy resin having the above-described glass transition temperature, the coated film strength and the adhesion strength increase.

As the epoxy compound, a compound having an epoxy group and a low molecular weight that is less than the above epoxy resin (polymer) can be used. In one embodiment, the epoxy compound may function as a crosslinking agent, and may be crosslinked and cured by an epoxy group in the compound. The predetermined quantity of epoxy compound imparts excellent heat resistance and adhesion to the electroless plating undercoat film. Examples of the epoxy compound include TEPIC-HP manufactured by Nissan Chemical Corporation.

The number of epoxy groups that the epoxy compound and the epoxy resin described above have per one molecule is not particularly limited, and may be, for example, 1 or more, 2 or more, or 3 or more. The upper limit is not particularly limited, and is, for example, 6 or less.

### [Phenolic Compound]

When a polyaniline complex is contained as a conductive polymer, the electroless plating undercoat film may further contain a phenolic compound having an effect of improving electric conductivity as a part of the polyaniline complex.

The phenolic compound is not particularly limited as long as the compound has a phenolic hydroxyl group. The compound having a phenolic hydroxyl group is a compound having one phenolic hydroxyl group, a compound having a plurality of phenolic hydroxyl groups, and a polymer compound composed of repeating units having one or more phenolic hydroxyl groups.

As the phenolic compound, known compounds can be used as appropriate.

### [Heat-Resistance Stabilizer]

The electroless plating undercoat film may further contain a heat-resistance stabilizer.

The heat-resistance stabilizer is an acidic substance or a salt of an acidic substance, and the acidic substance may be any of an organic acid (an acid of an organic compound) and an inorganic acid (an acid of an inorganic compound). In addition, the conductive polymer layer may contain a plurality of heat-resistance stabilizers.

### [Other Component]

The electroless plating undercoat film may further contain additives such as other resins, an inorganic material, a curing agent, a plasticizer, an organic conductive material, and the like.

Examples of the other resin include a binder base material, a matrix base material, and the like.

Specific examples of other resins include, for example, polyolefins such as polyethylene and polypropylene; chlorinated polyolefins, polystyrene, polyester, polyamide, polyacetal, polyethylene terephthalate, polycarbonate, polyethylene glycol, polyethylene oxide, polyacrylic acid, polyacrylic acid ester, polymethacrylic acid ester, polyvinyl alcohol, and the like.

In addition, in place of the above resin, or together with the resin, a thermosetting resin such as a phenol resin and a melamine resin, or a precursor capable of forming these thermosetting resins may be contianed.

The inorganic material is added, for example, for the purpose of improving mechanical properties such as strength, surface hardness, dimensional stability, or the like, or improving electrical properties such as conductivity.

Specific examples of the inorganic material include, for example, silica (silicon dioxide), titania (titanium dioxide), alumina (aluminum oxide), Sn-containing In₂O₃ (ITO), Zn-containing In₂O₃, a co-substituted compound of In₂O₃ (oxide in which tetravalent element and divalent element are substituted with trivalent In), Sb-containing SnO₂ (ATO), ZnO, Al-containing ZnO (AZO), Ga-containing ZnO (GZO), and the like.

The curing agent is added, for example, for the purpose of improving mechanical properties such as strength, surface hardness, dimensional stability, or the like. Specific examples of the curing agent include, for example, a thermosetting agent such as a phenol resin, and a photocuring agent based on an acrylate-based monomer and a photopolymerizable initiator.

The plasticizer is added, for example, for the purpose of improving mechanical properties such as tensile strength and bending strength.

Specific examples of the plasticizer include, for example, phthalic esters and phosphoric esters.

Examples of the organic conductive material include carbon materials such as carbon black, carbon nanotubes, and the like.

### [Content of Each Component in the Electroless Plating Undercoat Film]

The content of the component (A) in the electroless plating undercoat film is not particularly limited, and is, for example, preferably 30 to 85% by mass, more preferably 30 to 80% by mass, still more preferably 35 to 70% by mass, and particularly preferably 40 to 70% by mass, based on the total of the component (A) and the component (B).

The content of the urethane resin in the electroless plating undercoat film is not particularly limited, and is, for example, preferably 1 to 100 parts by mass, more preferably from 5 to 50 parts by mass, based on 100 parts by mass of the total of the component (A) and the component (B). Incidentally, the content of the urethane resin in the electroless plating undercoat film may be reduced, for example, 10% by mass or less, 5% by mass or less, 1% by mass or less, or the electroless plating undercoat film may be configured not to contain the urethane resin.

The content of the epoxy resin in the electroless plating undercoat film is not particularly limited, and is, for example, preferably 0.2 to 30 parts by mass, more preferably 0.5 to 15 parts by mass, and still more preferably 0.7 to 10 parts by mass, based on 100 parts by mass of the total of the component (A) and the component (B). Incidentally, the content of the epoxy resin in the electroless plating undercoat film may be reduced, for example, 1% by mass or less, 0.5% by mass or less, 0.1% by mass or less, or the electroless plating undercoat film may be configured not to contain the epoxy resin.

From the viewpoint of further improving the heat resistance of the electroless plating undercoat film, regardless of having an acid value or having no acid value, the content of the polyvinyl ethanol resin may be, for example, 1% by mass or less, 0.5% by mass or less, 0.1% by mass or less, or the electroless plating undercoat film may be configured not to contain the polyvinyl ethanol resin.

The electroless plating undercoat film may be composed of, for example, 90% by mass or more, 95% by mass or more, 98% by mass or more, 99% by mass or more, 99.5% by mass or more, 99.9% by mass or more, or 100% by mass of the component (A) and the component (B).

The electroless plating undercoat film may be composed of, for example, 90% by mass or more, 95% by mass or more, 98% by mass or more, 99% by mass or more, 99.5% by mass or more, 99.9% by mass or more, or 100% by mass of the component (A), the component (B), and one or more components among the above components other than the component (A) and the component (B).

### [Composition for Forming an Electroless Plating Undercoat Film]

The composition for forming an electroless plating undercoat film according to one embodiment of the invention can be used for forming the electroless plating undercoat film described above.

The composition for forming an electroless plating undercoat film according to one embodiment of the invention contains (A) a conductive polymer, (C) a polyol resin having an acid value, and (D) a polyisocyanate compound.

For the components (A), (C) and (D) contained in the composition for forming an electroless plating undercoat film, the explanation described for the electroless plating undercoat film is also applicable.

In one aspect, the proportion of the total of the component (C) and the component (D) to the nonvolatile component in the composition for forming an electroless plating undercoat film is preferably 10 to 90% by mass.

The nonvolatile component is a component remaining in a composition after removing a component which volatilizes when a composition is heated and/or depressurized within a range in which a blending component in a composition does not cause a chemical change (volatile component), and is usually a component other than a solvent in a composition.

In one aspect, the molar ratio of isocyanate groups in the component (D) to hydroxyl groups in the component (C) is preferably 0.6 to 10.

In another embodiment, the composition for forming an electroless plating undercoat film contains the component (A), the component (C), the component (D), and the component (E).

For the component (E) contained in the composition for forming an electroless plating undercoat film, the explanation described for the electroless plating undercoat film is also applicable.

In another embodiment, the proportion of the total of the component (C), the component (D), and the component (E) to the nonvolatile component in the composition for forming an electroless plating undercoat film is preferably 10 to 90% by mass.

In another embodiment, it is preferable that the molar ratio of the isocyanate group in the component (D) to the sum of the hydroxyl group in the component (C) and the hydroxyl group in the component (E) be 0.6 to 10.

The composition for forming an electroless plating undercoat film may further contains a urethane resin, an epoxy resin, a phenolic compound, a heat-resistant stabilizer, and other components, which are described with respect to an electroless plating undercoat film.

### [Solvent]

The composition for forming an electroless plating undercoat film may further contain a solvent. Examples of the solvent include, but are not limited to, methanol, ethanol, isopropyl alcohol, 2-methoxyethanol, 2-ethoxyethanol, diacetone alcohol, 3-methoxy-1-butanol, 3-methoxy-3-methyl-1-butanol, ethylcarbitol, acetone, methyl ethyl ketone, methyl isobutyl ketone, toluene, cyclohexanone, ethylcyclohexane, isophorone, sorbentonaphsa, tetrahydrofuran, diethyl ether, n-butyl acetate, n-butanol, propylene glycol monomethyl ether acetate, y-butyrolactone, tetralin, 2-butoxy-2-ethoxyethanol, propylene glycol monopropyl ether, dipropylene glycol monopropyl ether, propylene glycol monobutyl ether, 1,3-dimethylimidazolidinone, N-methylpyrrolidone, and the like. One kind of these may be used alone, or two or more kinds of these may be used in combination.

### [Content of Each Component in the Composition for Forming an Electroless Plating Undercoat Film]

The content of the component (A) in the composition for forming an electroless plating undercoat film is not particularly limited, and is, for example, preferably 10 to 85% by mass, more preferably 15 to 80% by mass, still more preferably 20 to 70% by mass, and particularly preferably 25 to 60% by mass, based on the total of the component (A), the component (C), the component (D), and the component (E).

The total content of the components (C) and (E) in the composition for forming an electroless plating undercoat film is not particularly limited, and is, for example, preferably 10 to 65% by mass, more preferably 15 to 60% by mass, still more preferably 20 to 60% by mass, based on the total of the component (A), the component (C), the component (D), and the component (E).

The content of the component (D) in the composition for forming an electroless plating undercoat film is not particularly limited, and is, for example, preferably 0.5 to 30% by mass, more preferably 1 to 25% by mass, and still more preferably 1 to 20% by mass, based on the total of the component (A), the component (C), the component (D), and the component (E). The content of the component (D) in the composition for forming an electroless plating undercoat film may be 6 to 30% by mass, 7 to 30% by mass, or 8 to 30% by mass, based on the total of the component (A), the component (C), the component (D), and the component (E).

The content of the urethane resin in the composition for forming an electroless plating undercoat film is not particularly limited, and is, for example, 1 to 100 parts by mass, more preferably 5 to 50 parts by mass, based on 100 parts by mass of the total of the component (A), the component (C), the component (D), and the component (E). Incidentally, the content of the urethane resin in the composition for forming an electroless plating undercoat film may be reduced, for example, 10% by mass or less, 5% by mass or less, 1% by mass or less, or the electroless plating undercoat film may be configured not to contain the urethane resin.

The content (total content in the case of a plurality of kinds) of one or more kinds selected from the group consisting of an epoxy resin and an epoxy compound in the composition for forming an electroless plating undercoat film is not particularly limited, and is preferably 0.2 to 30 parts by mass, more preferably 0.5 to 15 parts by mass, and still more preferably 0.7 to 10 parts by mass, based on 100 parts by mass of the total of the component (A), the component (C), the component (D), and the component (E). Incidentally, the content of the epoxy resin in the composition for forming an electroless plating undercoat film may be reduced, for example, 1% by mass or less, 0.5% by mass or less, 0.1% by mass or less, or the electroless plating undercoat film may be configured not to contain the epoxy resin.

The content of the solvent in the composition for forming an electroless plating undercoat film is not particularly limited, and can be appropriately adjusted according to the method of forming the undercoat film. For example, in the case of screen printing, the content of the solvent is preferably 50 to 2000 parts by mass, more preferably 100 to 1000 parts by mass, and still more preferably 100 to 600 parts by mass, based on 100 parts by mass of the total of the component (A), the component (C), the component (D), and the component (E). For example, in the case of bar coating process, the content of the solvent is preferably 100 to 5000 parts by mass, more preferably 500 to 4000 parts by mass, and still more preferably 1000 to 3000 parts by mass, based on 100 parts by mass of the total of the component (A) and the component (B).

From the viewpoint of further improving the heat resistance of the electroless plating undercoat film, regardless of having an acid value or having no acid value, the content of the polyvinyl ethanol resin may be, for example, 1% by mass or less, 0.5% by mass or less, 0.1% by mass or less, or the composition for forming an electroless plating undercoat film may be configured not to contain the polyvinyl ethanol resin.

The composition for forming an electroless plating undercoat film may contain, for example, 90% by mass or more, 95% by mass or more, 98% by mass or more, 99% by mass or more, 99.5% by mass or more, 99.9% by mass or more, or 100% by mass of the component (A), the component (C) and the component (D), or the component (A), the component (C), the component (D), and the component (E) other than the solvent.

The composition for forming an electroless plating undercoat film may contain, for example, 90% by mass or more, 95% by mass or more, 98% by mass or more, 99% by mass or more, 99.5% by mass or more, 99.9% by mass or more, or 100% by mass of the component (A), the component (C), the component (D), and one or more components among the above components other than the component (A), the component (C), and the component (D), or the component (A), the component (C), the component (D), the component (E), and one or more components among the above components other than the component (A), the component (C), the component (D), and the component (E), other than the solvent.

### [Method for Manufacturing an Electroless Plating Undercoat Film]

The method for manufacturing an electroless plating undercoat film of the invention uses the composition for forming an electroless plating undercoat film of the invention. This method for manufacturing is not particularly limited as long as the composition for forming an electroless plating undercoat film of the invention is used, and examples thereof include a coating method in which the composition for forming an electroless plating undercoat film of the invention is coated on a base material by bar coating process and dried.

### [Plating Laminate]

The plating laminate of the invention contains a base material, the above-mentioned electroless plating undercoat film, and an electroless plating layer containing a metal, and the electroless plating layer and the electroless plating undercoat film are directly in contact with each other.

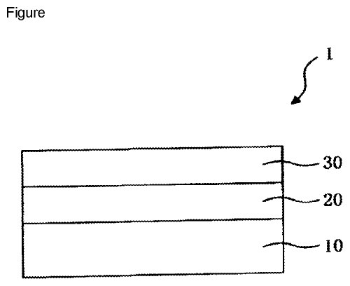

FIG. 1 is a schematic diagram showing a layer configuration of one embodiment of the plating laminate of the invention.

A plating laminate 1 contains an electroless plating undercoat film 20 and an electroless plating layer 30 by laminating in this order on a base material 10.

The plating laminate of the invention can be manufactured by a method for manufacturing the plating laminate of the invention, which will be described later.

### [Base Material]

The base material is not particularly limited, and may be a metal, an inorganic material (ceramics, glass, or the like), a wood, or a resin. Further, the base material may be a base material in which a metal is completely covered with a resin, a composite material of an inorganic-based material and a resin (for example, FRP, glass epoxy composite material), or the like. Examples of the type of the resin include polycarbonate resins, acrylic resins, nylon resins, polyimide resins, polyester resins, styrene resins, syndiotactic polystyrene resins, LCP (liquid crystal polymer) resins, phenolic resins, PPS (polyphenylene sulfide) resins, and the like. Among these, the base material be composed of polycarbonate resins, polyester resins, polyimide resins, syndiotactic polystyrene resins, liquid crystal polymer resins, or polyphenylene sulfide resins.

The electroless plating undercoat film adheres well not only to the resin base material but also to a base material having water resistance such as ceramics, glass, woods, and the like, and stables the growth of the electroless plating layer during the electroless plating.

In one aspect, the dielectric loss tangent of the substrate is preferably lower, and is 0.015 or less, preferably 0.01 or less, more preferably 0.005 or less. As a result, when the plating laminate is used as a circuit substrate for transmitting, for example, a high-frequency electric signal, the transmission loss can be reduced. The dielectric loss tangent is measured by the cavity resonator method (JIS R1641:2007) at a measuring frequency of 10 GHz and a temperature of 25° C. using a measuring device (Network Analyzer “E8361A” manufactured by Keysight Technologies).

### [Electroless Plating Layer (Metal Layer)]

Examples of the metal species of the electroless plating layer include one or more metals selected from the group consisting of copper, nickel, gold, palladium, silver, tin, cobalt, and platinum. Among these, copper is preferred. In addition to these metals, elements such as phosphorus, boron, iron, and the like may be contained in the electroless plating layer. The method for forming is as described later.

In one aspect, it is preferable that the surface roughness Rz_{JIS} of the surface of the electroless plating undercoat film in the electroless plating layer be smaller, and may be, for example, 0.5 μm or less, 0.45 μm or less, 0.40 μm or less, 0.35 μm or less, 0.3 μm or less, 0.25 μm or less, 0.2 μm or less, 0.15 μm or less, 0.1 μm or less, 0.08 μm or less, 0.05 μm or less, or 0.02 μm or less. When the plating laminate is used as a circuit substrate for transmitting, for example, a high-frequency electric signal, the transmission loss can be reduced. The lower limit of the surface roughness Rz_{JIS} is not particularly limited, and may be, for example, 0.005 μm or more, 0.007 μm or more, or 0.01 μm or more. The surface roughness Rz_{JIS} is a ten-point mean roughness measured in accordance with JIS B 0601 2001. When the electroless plating layer is formed on the electroless plating undercoat film by electroless plating, the surface roughness Rz_{JIS} measured on the surface of the electroless plating undercoat film (the surface on which the electroless plating layer is later formed) prior to being subjected to electroless plating is the surface roughness Rz_{JIS} of the surface of the electroless plating undercoat film side in the electroless plating layer.

The film thickness of the electroless plating layer is not particularly limited. In one embodiment, the thickness of the electroless plating layer may be, for example, 0.1 μm or more, 0.3 μm or more, 0.5 μm or more, 0.8 μm or more, 1 μm or more, 5 μm or more, 10 μm or more, 18 μm or more, or 30 μm or more. The thickness of the electroless plating layer may be, for example, 500 μm or less, 300 μm or less, 200 μm or less, 150 μm or less, 100 μm or less, or 50 μm or less.

### [Application of the Plating Laminate]

The application of the plating laminate is not particularly limited, and the plating laminate can be used as, for example, a circuit substrate, an antenna, an electromagnetic wave shielding, or the like. Further, in one embodiment, the device incorporating one or more selected from the group consisting of these circuit substrate, antenna, and electromagnetic wave shielding is provided.

### [Circuit Substrate]

In circuit substrate applications, the metal layer (electroless plating layer) is used in applications for transmitting electric signals. According to one embodiment of the circuit substrate, transmission loss can be prevented, regardless of the frequency of electric signals. Further, in one embodiment, the metal layer is used in applications for transmitting high-frequency electric signals having a frequency of 1 GHz or more. The high-frequency electrical signals may have a frequency of 3 GHz or more, 4 GHz or more, 5 GHz or more, 7 GHz or more, 10 GHz or more, 15 GHz or more, 20 GHz or more, 25 GHz or more, 30 GHz or more, 50 GHz or more, 80 GHz or more, 100 GHz or more, or 110 GHz or more, for example. The upper limit of the frequency is not particularly limited, and may be, for example, 200 GHz or less. According to one embodiment of the circuit substrate, transmission loss can be prevented even when transmitting such high-frequency electric signals. The configuration of the circuit substrate is not particularly limited and may be, for example, a printed wiring board (PWB), a printed circuit board (PCB), or a flexible printed circuit (FPC).

### [Antenna]

In antenna applications, the metal layer (electroless plating layer) is used in applications for transmitting and receiving radio waves. In one embodiment, the metal layer is used in applications for transmitting and receiving high-frequency radio waves. The frequency of the high-frequency radio wave may be, for example, 3 GHz or more, 4 GHz or more, 5 GHz or more, 7 GHz or more, 10 GHz or more, 15 GHz or more, 20 GHz or more, 25 GHz or more, 30 GHz or more, 50 GHz or more, 80 GHz or more, 100 GHz or more, or 110 GHz or more. The upper limit of the frequency is not particularly limited, and may be, for example, 200 GHz or less.

### [Electromagnetic Wave Shield]

In electromagnetic wave shield applications, the metal layer (electroless plating layer) is used in applications for shielding electromagnetic waves.

### [Method for Manufacturing a Plating Laminate]

A method for manufacturing a plating laminate according to one embodiment of the invention contains (1) forming an electroless plating undercoat film on a base material using a composition for forming an electroless plating undercoat film, and (2) forming an electroless plating layer containing a metal on the electroless plating undercoat film.

The formation of the electroless plating undercoat film can be performed by the above-described method for manufacturing the electroless plating undercoat film.

Before forming the electroless plating undercoat film the surface of the base material can be subjected to one or more treatments selected from the group consisting of an active energy ray irradiation treatment, a corona treatment, and a frame treatment.

In this specification, an “active energy ray” has an activity of modifying a surface of the base material, and one capable of improving adhesiveness between the base material and the electroless plating undercoat film by such modification can be used. The evaluation method of “adhesiveness before plating” described in Example is used as a method for evaluating the improvement of adhesiveness. Examples of such active energy rays include ultraviolet ray, electrons ray, and X-ray, and among these, ultraviolet ray is preferred. The ultraviolet ray is not particularly limited, and for example, ultraviolet ray from a high-pressure mercury lamp or a metal halide lamp as a light source can be used.

After the formation of the electroless plating undercoat film, it is preferable to perform a degreasing step before the formation of the electroless plating layer.

In the degreasing step, the surface of the electroless plating undercoat film is degreased and washed with a solvent such as a surfactant or an alcohol to improve wettability.

As the surfactant, an anionic, cationic, or nonionic surfactant can be used as appropriate, and a cationic surfactant is preferred. When a cationic surfactant is used, the cationic surfactant is diluted to 1 to 3% with ion-exchanged water or the like and used, for example.

After forming the above electroless plating undercoat film, preferably after the degreasing step, the electroless plating undercoat film is preferable to contact the Pd compound solution in order to support Pd metal (catalyst metal) which carries the catalytic action of electroless plating on the undercoat film.

When the Pd compound solution is contacted, a conductive polymer such as a polyaniline complex adsorbs Pd ions, and due to the reducing action of the conductive polymer, Pd ions are reduced to Pd metal. The reduced Pd, i.e. Pd in a metal state, provides the catalytic action in electroless plating.

The amount of Pd deposited per unit area (including Pd ions and Pd metal) is preferably 1.7 μg/cm² or more, and more preferably 2.5 μg/cm² or more.

As the Pd compound, palladium chloride is preferred. As the solvent, hydrochloric acid is usually used. However, it is sufficient that Pd is present in an aqueous solution in an ionic state, and the solvent is not limited to an aqueous hydrochloric acid solution. Examples of the Pd compound solution include palladium chloride solution and the like, and more specifically include, for example, 0.02% palladium chloride-0.01% aqueous hydrochloric acid solution (pH 3).

The contact temperature with the Pd compound solution is usually 20 to 50° C., preferably 30 to 40° C., and the contact time is usually 0.1 to 10 minutes, preferably 1 to 5 minutes.

Next, in order to form a metal-containing layer (plating layer) on the undercoat film, the substrate obtained above is contacted with an electroless plating solution. When the undercoat film and the electroless plating solution are contacted with each other, the supported Pd metal acts as a catalyst, and a plating layer is formed on the undercoat film.

The electroless plating solution preferably contains one or more metals selected from the group consisting of copper, nickel, gold, palladium, silver, tin, cobalt, and platinum. In addition, elements such as phosphorus, boron, iron, and the like may be contained in the electroless plating solution in addition to these metals.

The contact temperature with the electroless plating solution varies depending on the type of the plating bath and thickness, and is, for example, about 20 to 50° C. in the case of a low-temperature bath and 50 to 90° C. in the case of a high-temperature bath.

The contact time with the electroless plating solution also varies depending on the type of the plating bath and thickness, and is, for example, 1 to 120 minutes. The plating layer can be formed by electroless plating alone, or by providing a thin metal film by electroless plating and then further providing the same or a different metal film by electroplating.

### EXAMPLES

Hereinafter, examples of the invention will be described, but the invention is not limited by these examples in any way.

### Production Example 1

### [Production of the Polyaniline Complex]

A solution obtained by dissolving 37.8 g of “Aerosol OT” (sodium di-2-ethylhexylsulfosuccinate) (AOT) and 1.47 g of “Sorbon T-20” (manufactured by Toho Chemical Industry Co., Ltd.) as a nonionic emulsifier having a polyoxyethylene sorbitan fatty acid ester structure in 600 mL of toluene was placed in a 6 L separable flask placed under a stream of nitrogen, and 22.2 g of aniline was further added to this solution. Thereafter, 1800 mL of 1 M phosphoric acid was added to the solution, and the temperature of the solution having two liquid phases of toluene and water was cooled to 5° C.

When the internal temperature of the solution reached 5° C., the solution was stirred at 390 revolutions per minute. A solution of 65.7 g of ammonium persulfate dissolved in 600 mL of 1 M phosphoric acid was added dropwise over a period of 2 hours using a dropping funnel. The reaction was carried out for 18 hours from the start of the dropwise addition, while the internal temperature of the solution was kept at 5° C. Thereafter, the reaction temperature was increased to 40° C., and the reaction was continued for 1 hours. Thereafter, the reaction solution was allowed to stand, and the toluene phase was separated. To the obtained toluene phase, 1500 mL of toluene was added, washed once with 500 mL of 1 M phosphoric acid and 3 times with 500 mL of ion-exchanged water, and the toluene phase was separated by standing, and condensation for concentration adjustment was performed to obtain 900 g of a polyaniline complex toluene solution. The concentration of the polyaniline complex of this polyaniline complex toluene solution was 5.7% by mass.

The obtained polyaniline complex toluene solution was dried under reduced pressure in a water bath at 60° C., and then dried and solidified to obtain 51.3 g of a polyaniline complex (powder).

The weight average molecular weight of the polyaniline molecule in this polyaniline complex was 72,000 g/mol, and the molecular weight distribution was 2.0.

### Example 1

### (1) Preparation of the Composition for Forming an Electroless Plating Undercoat Film

4.0 g of a polyester polyol resin having an acid value (manufactured by Toyobo Co., Ltd.: Vylon GK810, acid value 5 mgKOH/g) was dissolved in a solvent composed of 0.6 g of toluene (manufactured by FUJIFILM Wako Pure Chemical Corporation), 3.0 g of cyclohexanone (manufactured by FUJIFILM Wako Pure Chemical Corporation), and 2.4 g of propylene glycol monobutyl ether (manufactured by FUJIFILM Wako Pure Chemical Corporation) to obtain a polyester polyol resin solution.

On the other hand, 1.40 g of the polyaniline complex obtained in Production Example 1 was dissolved in a solvent composed of 4.60 g of toluene, 27.60 g of cyclohexanone, and 13.80 g of propylene glycol monopropyl ether (manufactured by Tokyo Chemical Industry Co., Ltd.) to obtain a polyaniline complex solution.

To the above-mentioned polyaniline complex solution, 1.50 g of the above-mentioned polyester polyol resin solution, 3.20 g of a polyester polyol resin solution having no acid value (manufactured by Toyobo Co., Ltd.: vylon UR-1350, concentration of polyester polyol resin having no acid value: 33% by mass), and 0.47 g of a blocked isocyanate solution (manufactured by Jujo Chemical Co., Ltd.: JA-980, concentration of blocked isocyanate: 88% by mas) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 6.9. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 3.5. In the calculation of these “molar ratios”, the amount of hydroxyl groups is a value calculated from the amount of hydroxyl groups per 1 g of each polyol resin determined by the method of measuring the hydroxyl value of the polyester polyol resin described above and the mass of each polyol resin blended in the composition.

### (2) Formation of the Electroless Plating Undercoat Film

The above-mentioned composition for forming an electroless plating undercoat film was applied to a polyimide film (manufactured by Toray Industries, Inc.: Kapton 200EN) using a barcoater #8. The coated film was dried at 150° C. for 30 minutes to obtain a film with an electroless plating undercoat film.

The acid value of the electroless plating undercoat film and the surface roughness Rz_{JIS} of the surface of the electroless plating undercoat film were measured by the following measuring method, and the adhesiveness before plating (adhesiveness of the electroless plating undercoat film to the base material) was evaluated by the following evaluating method. The results are shown in Table 1.

### (Measurement of the Acid Value of the Electroless Plating Undercoat Film)

The electroless plating undercoat film was scraped off from the obtained test piece using a cutter knife and minced finely to obtain a sample. The acid value was measured in accordance with JIS-K-0070:1992 and used as the acid value of the electroless plating undercoat film. The acid value referred to here is the number of mg of potassium hydroxide (KOH) required to neutralize the acidic component contained in 1 g of electroless plating undercoat film.

When the acid value of the electroless plating undercoat film is measured for a plated test piece described later, the plated film can be removed by nitric acid and then the test piece can be subjected to the same measurement method as described above.

### (Measurements of the Surface Roughness Rz_{JIS})

The surface roughness Rz_{JIS} of the surface of the electroless plating undercoat film in the obtained test piece (the surface opposite to the base material in the electroless plating undercoat film) was measured in accordance with JIS B 0601:2001. The measured values are shown in Table 1 as the surface roughness Rz_{JIS} of the electroless plating undercoat film in the metal layer (electroless plating layer) formed on the electroless plating undercoat film.

### (Evaluation of Adhesiveness Before Plating)

The obtained test piece (for evaluating adhesiveness) was subjected to an adhesion test in accordance with JIS K5600-5-6 (1999). Evaluation was performed according to the following criteria as defined in JIS K5600-5-6, and Categories 0 and 1 were defined as “∘” (acceptable), and Categories 2 to 5 were defined “x” (rejected). The adhesiveness before plating can reflect the adhesiveness of the electroless plating undercoat film to the base material. The results are shown in Table 1.

0: The edges of the cuts are perfectly smooth and there is no peeling in any of the grid eyes.
1: The coat film is peeled off in small areas at the intersection of the cuts. The portion affected by the cross-cutting portion does not clearly exceed 5%.
2: The coat film is peeled off along the edges of the cut and/or at the intersection. The portion affected by the cross-cutting portion clearly exceeds 5% but never exceeds 15%.
3: The coat film is partially or fully peeled off in large areas along the edges of the cut and/or the various portions of the grid eye is partially or fully peeled. The portion affected by the cross-cutting portion clearly exceeds 15% but never exceeds 35%.
4: The coat film is partially or fully peeled off in large areas along the edges of the cut and/or a few grid eyes are partially or fully peeled off. The portion affected by the cross-cutting portion clearly exceeds 35%.
5: The coat film is peeled off to the extent that it cannot be classified even in Category 4.

### (3) Electroless Plating

The film with an electroless plating undercoat film was cut out to 5×10 cm to obatin a test piece. This test piece was immersed in 2.5% by mass aqueous solution of a surfactant (“ACE CLEAN” manufactured by Okuno Chemical Industries Co., Ltd.) for 5 minutes at 55° C. Thereafter, the surface of the test piece was washed with running water and then immersed in 10% by mass aqueous solution of sodium bisulfite (manufactured by FUJIFILM Wako Pure Chemical Corporation) for 5 minutes at 60° C. Further, the surface of the test piece was washed with running water and subjected to degreasing treatment.

The entire test piece after the degreasing treatment was immersed in 20-fold dilution of a catalytic treatment agent activator (hydrochloric acidic Pd compound solution, manufactured by Okuno Chemical Industries Co., Ltd.) for 5 minutes at 30° C., and a treatment for supporting metal Pd (electroless plating catalyst) on the electroless plating undercoat film was performed.

The test piece after the catalyst supporting treatment was subjected to a plating treatment at 52° C. for 30 minutes using an electroless copper plating solution (“Circuposit 4500,” manufactured by Rohm and Haas Electronic Materials LLC) to form an electroless copper plating layer (a metal layer containing copper), and then washed with running water and dried with warm air (80° C.) to obtain a plated test piece.

### (4) Evaluation of the Plated Test Piece

### (Evaluation of Adhesiveness After Plating)

The plated test piece was subjected to the adhesiveness test in the same manner as (Evaluation of adhesiveness before plating) and evaluated using the same criteria. The adhesiveness after plating may reflect both the adhesiveness of the electroless plating undercoat film to the base material and the adhesiveness of the electroless copper plating layer to the electroless plating undercoat film. The results are shown in Table 1.

### (Evaluation of Heat Resistance)

The plated test piece was further laminated with 35 μm of copper by electroplating. A solder float test was conducted in which the plated surface of the test piece was placed in contact with a solder bath (FX301B, manufactured by HAKKO Corporation; type of solder: ECO Solder M705, manufactured by Senju Metal Industry Co., Ltd.) set at 260° C. for 5 seconds, and the heat resistance was evaluated using the following criteria. The results are shown in Table 1.

∘: No peeling or cracking is visually observed in the plating film or electroless plating undercoat film.
x: Peeling or cracking is visually observed in the plating film or electroless plating undercoat film.

### Example 2

Measurements and evaluations were conducted in the same manner as in Example 1, except that the composition for forming electroless plating undercoat film was prepared in the following manner. The results are shown in Table 1.

### [Preparation of the Composition for Forming an Electroless Plating Undercoat Film]

0.10 g of a surface modifier (manufactured by SHIKOKU CHEMICALS CORPORATION: VD-3) was suspended in a solvent composed of 4.60 g of toluene, 27.60 g of cyclohexanone, and 13.80 g of propylene glycol monopropyl ether. Then, 1.40 g of the polyaniline complex obtained in Production Example 1 was dissolved in this suspension. To the above polyaniline complex solution, 1.35 g of the polyester polyol resin solution described in Example 1, 3.35 g of a polyester polyol resin solution having no acid value (manufactured by Toyobo Co., Ltd.: Vylon UR-1350) and 0.48 g of a blocked isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 7.8. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 3.6.

### Example 3

Measurements and evaluations were conducted in the same manner as in Example 2, except that the composition for forming electroless plating undercoat film was prepared in the following manner. The results are shown in Table 1.

### [Preparation of the Composition for Forming an Electroless Plating Undercoat Film]

In Example 2, the blending amount of a polyaniline complex was changed to 0.95 g, the blending amount of a polyester polyol resin solution was changed to 2.20 g, the blending amount of a polyester polyol resin solution having no acid value was changed to 3.20 g, and the blending amount of a block isocyanate solution was changed to 0.50 g to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 5.0. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 3.0.

### Example 4

Measurements and evaluations were conducted in the same manner as in Example 1, except that the composition for forming electroless plating undercoat film was prepared in the following manner. The results are shown in Table 1.

### [Preparation of the Composition for Forming an Electroless Plating Undercoat Film]

0.10 g of a surface modifier (manufactured by SHIKOKU CHEMICALS CORPORATION: VD-3) was suspended in a solvent composed of 4.60 g of toluene, 27.30 g of cyclohexanone, and 13.70 g of propylene glycol monopropyl ether. Then, 1.40 g of the polyaniline complex obtained in Production Example 1 was dissolved in this suspension. To this polyaniline complex solution, 1.50 g of a polyester polyol resin solution having an acid value (manufactured by Toyobo Co., Ltd.: Vylon UR-1700, acid value 26 mgKOH/g, concentration of polyester polyol resin having an acid value: 30% by mass), 3.70 g of a polyester polyol resin solution having no acid value (manufactured by Toyobo Co., Ltd.: Vylon UR-1350), and 0.51 g of a block isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 3.0. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 2.1.

### Example 5

Measurements and evaluations were conducted in the same manner as in Example 1, except that the composition for forming electroless plating undercoat film was prepared in the following manner. The results are shown in Table 1.

### [Preparation of the Composition for Forming an Electroless Plating Undercoat Film]

0.10 g of a surface modifier (manufactured by SHIKOKU CHEMICALS CORPORATION: VD-3) was suspended in a solvent composed of 4.60 g of toluene, 27.30 g of cyclohexanone, and 13.80 g of propylene glycol monopropyl ether. Then, 1.40 g of the polyaniline complex obtained in Production Example 1 was dissolved in this suspension. To this polyaniline complex solution, 2.10 g of a polyester polyol resin solution having an acid value (manufactured by Toyobo Co., Ltd.: Vylon UR-1700, acid value 26 mgKOH/g), 2.00 g of a polyester polyol resin solution having no acid value (manufactured by Jujo Chemical Co., Ltd.: PL-2 Medium, concentration of a polyester polyol resin having no acid value: 49% by mass), and 0.46 g of a blocked isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 1.9. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 1.6.

### Comparative Example 1

Measurements and evaluations were conducted in the same manner as in Example 1, except that the composition for forming electroless plating undercoat film was prepared in the following manner. The results are shown in Table 1.

### [Preparation of the Composition for Forming an Electroless Plating Undercoat Film]

0.10 g of a surface modifier (manufactured by SHIKOKU CHEMICALS CORPORATION: VD-3) was suspended in a solvent composed of 4.60 g of toluene, 27.30 g of cyclohexanone, and 13.70 g of propylene glycol monopropyl ether. Then, 1.40 g of the polyaniline complex obtained in Production Example 1 was dissolved in this suspension. To this polyaniline complex solution, 2.50 g of a urethane resin solution having an acid value (manufactured by Dainichiseika Color & Chemicals Mfg. Co., Ltd., DAIFERAMINE MAU1008L, acid value 2 mgKOH/g, concentration of a urethane resin having an acid value: 30% by mass), 2.80 g of a polyester polyol resin solution having no acid value (manufactured by Toyobo Co., Ltd., Vylon UR-1350), and 0.35 g of a block isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the component (C) (polyol resin having an acid value) is not contained. The molar ratio of the isocyanate group in the component (D) (polyisocyanate compound) to the sum of the hydroxyl group in the component (C) (polyol resin having an acid value: not contained here) and the hydroxyl group in the component (E) (polyol resin having no acid value) is 6.0.

### Comparative Example 2

Measurements and evaluations were conducted in the same manner as in Example 1, except that the composition for forming electroless plating undercoat film was prepared in the following manner. The results are shown in Table 1.

### [Preparation of the Composition for Forming an Electroless Plating Undercoat Film]

0.10 g of a surface modifier (manufactured by SHIKOKU CHEMICALS CORPORATION: VD-3) was suspended in a solvent composed of 4.60 g of toluene, 27.60 g of cyclohexanone, and 13.80 g of propylene glycol monopropyl ether. Then, 1.60 g of the polyaniline complex obtained in Production Example 1 was dissolved in this suspension. To this polyaniline complex solution, 5.10 g of a polyester polyol resin solution having an acid value (manufactured by Toyobo Co., Ltd.: Vylon UR-1700, acid value 26 mgKOH/g) and 0.46 g of a blocked isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 0.8. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 0.7.

### Comparative Example 3

Measurements and evaluations were conducted in the same manner as in Example 2, except that the composition for forming electroless plating undercoat film was prepared in the following manner. The results are shown in Table 1.

### [Preparation of the Composition for Forming an Electroless Plating Undercoat Film]

In Example 2, the blending amount of a solvent was changed to 4.00 g of toluene, 24.00 g of cyclohexanone, and 12.00 g of propylene glycol monopropyl ether, the blending amount of a polyaniline complex was changed to 1.00 g, the blending amount of a polyester polyol resin solution was changed to 0.12 g, the blending amount of a polyester polyol resin solution having no acid value was changed to 4.40 g, and the blending amount of a block isocyanate solution was changed to 0.56 g to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 102.5. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 5.7.

TABLE 1

| | | | | | | Comp. | Comp. | Comp. |
|---|---|---|---|---|---|---|---|---|
| | Ex. 1 | Ex. 2 | Ex. 3 | Ex. 4 | Ex. 5 | Ex. 1 | Ex. 2 | Ex. 3 |
| Acid value of the electroless plating | 0.86 | 0.76 | 1.28 | 10.78 | 15.54 | 1.44 | 36.44 | 0.08 |
| undercoat film [mgKOH/g] | | | | | | | | |
| Surface roughness Rz_{JIS} of the | 0.15 | 0.22 | 0.21 | 0.18 | 0.22 | 0.20 | 0.20 | 0.24 |
| surface of the electroless plating | | | | | | | | |
| undercoat film | | | | | | | | |
| (Surface roughness Rz_{JIS} of the | | | | | | | | |
| electroless plating layer) [μm] | | | | | | | | |
| Adhesiveness before plating | ∘ | ∘ | ∘ | ∘ | ∘ | ∘ | ∘ | ∘ |
| Adhesiveness after plating | ∘ | ∘ | ∘ | ∘ | ∘ | ∘ | x | x |
| Heat resistance | ∘ | ∘ | ∘ | ∘ | ∘ | x | — | — |

### Evaluation

From Table 1, it can be seen that the electroless plating undercoat film according to Examples 1 to 5, which contains (A) a conductive polymer, and further contains (B) a reactant of a polyol resin having an acid value and a polyisocyanate compound, and has an acid value of 0.1 mgKOH/g to 30 mgKOH/g, can achieve both good adhesiveness and heat resistance. Further, it can be seen that the surface of the electroless plating undercoat film side in the electroless plating layer is smoothed, and even such a smoothed surface, excellent adhesiveness is exhibited in Examples 1 to 5.

Incidentally, in Examples 1 to 5, the cross section of the plated test piece was observed by electrons microscopy, and it was confirmed that the surface smoothness of the electroless plating undercoat film is maintained, and the interface with the metal layer is smooth.

On the other hand, in Comparative Example 1, although the electroless plating treatment could be carried out without any problem, peeling occurred in a part of the plating film in the heat resistance test. In Comparative Example 1, a resin having an acid value (urethane resin) is blended, but since the resin is not a polyol resin, it does not react with the blocked isocyanate and does not contribute to curing of the undercoat film. Therefore, in Comparative Example 1, it is estimated that the result is inferior in heat resistance.

In Comparative Example 2 in which the acid value of the electroless plating undercoat film exceeded 30 mgKOH/g, and Comparative Example 3 in which the acid value of the electroless plating undercoat film was less than 0.1 mgKOH/g, peeling occurred on a part of copper layer formed during the electroless plating treatment due to insufficient adhesion. Therefore, the evaluation of the heat resistance is omitted.

### Example 6

Measurements and evaluations were conducted in the same manner as in Example 1, except that the composition for forming electroless plating undercoat film was prepared and an electroless plating undercoat film was formed in the following manner. The results are shown in Table 2.

### (1) Preparation of the Composition for Forming an Electroless Plating Undercoat Film

4.00 g of a polyester polyol resin having an acid value (manufactured by Toyobo Co., Ltd.: Vylon GK360, acid value 5 mgKOH/g) was dissolved in a solvent composed of 0.60 g of toluene (manufactured by FUJIFILM Wako Pure Chemical Corporation), 3.60 g of cyclohexanone (manufactured by FUJIFILM Wako Pure Chemical Corporation), and 1.80 g of propylene glycol monobutyl ether (manufactured by FUJIFILM Wako Pure Chemical Corporation) to obtain a polyester polyol resin solution.

On the other hand, 0.10 g of a surface modifier (manufactured by SHIKOKU CHEMICALS CORPORATION: VD-3) was suspended in a solvent composed of 4.60 g of toluene, 27.60 g of cyclohexanone, and 13.80 g of propylene glycol monopropyl ether. Then, 1.40 g of the polyaniline complex obtained in Production Example 1 was dissolved in this suspension to obtain a polyaniline complex solution.

To the above polyaniline complex solution, 5.00 g of the above polyester polyol resin solution and 0.08 g of a blocked isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 1.0. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 1.0.

### (2) Formation of the Electroless Plating Undercoat Film

The above-mentioned composition for forming an electroless plating undercoat film was applied to a polyimide film (manufactured by Toray Industries, Inc.: Kapton 300H) using a barcoater #8. The coated film was dried at 150° C. for 30 minutes to obtain a film with an electroless plating undercoat film.

### Example 7

Measurements and evaluations were conducted in the same manner as in Example 6, except that the composition for forming electroless plating undercoat film was prepared in the following manner. The results are shown in Table 2.

### [Preparation of the Composition for Forming an Electroless Plating Undercoat Film]

4.00 g of a polyester polyol resin having no acid value (manufactured by TOYOBO CO., LTD.: Vylon 226) was dissolved in a solvent composed of 0.60 g of toluene (manufactured by FUJIFILM Wako Pure Chemical Corporation), 3.60 g of cyclohexanone (manufactured by FUJIFILM Wako Pure Chemical Corporation), and 1.80 g of propylene glycol monopropyl ether (manufactured by FUJIFILM Wako Pure Chemical Corporation) to obtain a polyester polyol resin solution.

On the other hand, to a solvent composed of 4.60 g of toluene, 27.60 g of cyclohexanone, and 13.80 g of propylene glycol monopropyl ether, 0.45 g of an epoxy compound (manufactured by Nissan Chemical Corporation: TEPIC-HP, low molecular-weight compound having three epoxy groups in one molecule) was dissolved. Then, 2.40 g of the polyaniline complex obtained in Production Example 1 was dissolved in this solution to obtain a polyaniline complex solution.

To the above polyaniline complex solution, 4.90 g of the above polyester polyol resin solution, 0.40 g of a polyester polyol resin solution having an acid value (manufactured by Toyobo Co., Ltd.: Vylon UR-1700, acid value 26 mgKOH/g), 0.35 g of a polyester polyol resin solution having no acid value (manufactured by Toyobo Co., Ltd.: Vylon UR-1350), and 0.36 g of a block isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 7.9. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 1.3.

### Example 8

### (1) Preparation of the Composition for Forming an Electroless Plating Undercoat Film

4.00 g of a polyester polyol resin having no acid value (manufactured by TOYOBO CO., LTD.: Vylon 226) was dissolved in a solvent composed of 0.60 g of toluene (manufactured by FUJIFILM Wako Pure Chemical Corporation), 3.60 g of cyclohexanone (manufactured by FUJIFILM Wako Pure Chemical Corporation), and 1.80 g of propylene glycol monopropyl ether (manufactured by FUJIFILM Wako Pure Chemical Corporation) to obtain a polyester polyol resin solution.

On the other hand, 0.15 g of a surface modifier (manufactured by SHIKOKU CHEMICALS CORPORATION: VD-3) was suspended in a solvent composed of 4.60 g of toluene, 27.60 g of cyclohexanone, and 13.80 g of propylene glycol monopropyl ether. Then, 2.40 g of the polyaniline complex obtained in Production Example 1 was dissolved in this suspension to obtain a polyaniline complex solution.

To the above polyaniline complex solution, 4.90 g of the above polyester polyol resin solution, 0.40 g of a polyester polyol resin solution having an acid value (manufactured by Toyobo Co., Ltd.: Vylon UR-1700, acid value 26 mgKOH/g), 0.35 g of a polyester polyol resin solution having no acid value (manufactured by Toyobo Co., Ltd.: Vylon UR-1350), and 0.36 g of a block isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 7.9. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 1.3.

### (2) Formation of the Electroless Plating Undercoat Film

The surfaces of a syndiotactic polystyrene film (Zalec XG-110M, manufactured by Idemitsu Kosan Co.,Ltd.) (hereinafter referred to as “SPS film”) was surface-treated by irradiating 1500 mJ/cm² of ultraviolet light using a conveyor type UV-irradiating device (CSOT-40, manufactured by GS Yuasa Corporation).

The above-mentioned composition for forming an electroless plating undercoat film was applied to the SPS film subjected to the surface treatment using a barcoater #8. The coated film was dried at 150° C. for 30 minutes to obtain a film with an electroless plating undercoat film.

Measurement of the acid value of the electroless plating undercoat film, measurement of the surface roughness RzJIS, and evaluation of the adhesiveness before plating were measured and evaluated in the same manner as in Example 1. The results are shown in Table 2.

### (3) Electroless Plating

A plated test piece was obtained in the same manner as in Example 1 except that the electroless plating time was set to 10 minutes.

### (4) Evaluation of the Plated Ttest Piece

### (Evaluation of Adhesiveness After Plating)

The evaluation of adhesiveness after plating was measured and evaluated in the same manner as in Example 1. The results are shown in Table 2.

### (Evaluation of Heat Resistance (Heat Resistance 2))

The plated test piece was further laminated with 22 μm of copper by electroplating. The surface of the test piece was wetted with flux for lead-free solder (FS-200, manufactured by HAKKO Corporation). A solder float test was conducted in which the test piece was placed in contact with a solder bath (FX301B, manufactured by HAKKO Corporation; type of solder: ECO Solder M705, manufactured by Senju Metal Industry Co., Ltd.) set at 240° C. for 10 seconds, and the heat resistance was evaluated using the same criteria as in Example 1. The results are shown in Table 2. Since this evaluation of heat resistance differs from the evaluation of heat resistance in Examples 1 to 7 in terms of conditions, this evaluation is expressed as “heat resistance 2” in Table 2.

### Example 9

Measurements and evaluations were conducted in the same manner as in Example 8, except that the composition for forming electroless plating undercoat film was prepared in the following manner and the electroless plating undercoat film was formed. The results are shown in Table 2.

### (1) Preparation of the Composition for Forming an Electroless Plating Undercoat Film

4.00 g of a polyester polyol resin having no acid value (manufactured by TOYOBO CO., LTD.: Vylon 226) was dissolved in a solvent composed of 0.60 g of toluene (manufactured by FUJIFILM Wako Pure Chemical Corporation), 3.60 g of cyclohexanone (manufactured by FUJIFILM Wako Pure Chemical Corporation), and 1.80 g of propylene glycol monopropyl ether (manufactured by FUJIFILM Wako Pure Chemical Corporation) to obtain a polyester polyol resin solution.

On the other hand, 0.15 g of a surface modifier (manufactured by SHIKOKU CHEMICALS CORPORATION: VD-3) was suspended in a solvent composed of 4.60 g of toluene, 27.60 g of cyclohexanone, and 13.80 g of propylene glycol monopropyl ether. Then, 2.40 g of the polyaniline complex obtained in Production Example 1 was dissolved in this suspension to obtain a polyaniline complex solution.

To the above polyaniline complex solution, 4.00 g of a polyester polyol resin solution, 0.40 g of a polyester polyol resin solution having an acid value (manufactured by TOYOBO CO., LTD.: vylon UR-1700, acid value: 26 mgKOH/g), 1.45 g of a polyester polyol resin solution having no acid value (manufactured by TOYOBO CO., LTD.: vylon UR-1350), and 0.45 g of a blocked isocyanate solution (manufactured by Jujo Chemical Co., Ltd.: JA-980) were added and uniformly mixed to obtain a composition for forming an electroless plating undercoat film.

In the obtained composition for forming an electroless plating undercoat film, the molar ratio of the isocyanate group in the component (D) (polyisocyanate compound) to the hydroxyl group in the component (C) (polyol resin having an acid value) is 9.9. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 1.7.

### (2) Formation of the Electroless Plating Undercoat Film

Both surfaces of the SPS film were irradiated with 1500 mJ/cm² of ultraviolet ray to obtain an SPS film with surface treatment on both surfaces. The above composition for forming an electroless plating undercoat film was applied to one side of the SPS film with surface treatment on both surfaces using a barcoater #8. The coated film was dried at 150° C. for 10 minutes to form an electroless plating undercoat film on one surface. Next, the above composition for forming an electroless plating undercoat film was applied to the opposite surface using a barcoater #8. The coated film was dried at 150° C. for 30 minutes to obtain a film with electroless plating undercoat films on both surfaces.

### Example 10

Measurements and evaluations were conducted in the same manner as in Example 8, except that the composition for forming electroless plating undercoat film was prepared in the following manner. The results are shown in Table 2.

### [Preparation of the Composition for Forming an Electroless Plating Undercoat Film]

A composition for forming electroless plating undercoat film was prepared in the same manner as in Example 8, except that 4.60 g of toluene used in preparing the above polyaniline complex solution was replaced with 4.60 g of ethylcyclohexane (manufactured by Tokyo Chemical Industry Co., Ltd.).

In the obtained composition for forming an electroless plating undercoat film, the molar ratio of the isocyanate group in the component (D) (polyisocyanate compound) to the hydroxyl group in the component (C) (polyol resin having an acid value) is 7.9. In addition, the molar ratio of the isocyanate group in the component (D) (polyisocyanate compound) to the sum of the hydroxyl group in the component (C) (polyol resin having an acid value) and the hydroxyl group in the component (E) (polyol resin having no acid value) is 1.3.

TABLE 2

| | Ex. 6 | Ex. 7 | Ex. 8 | Ex. 9 | Ex. 10 |
|---|---|---|---|---|---|
| Acid value of the electroless | 2.80 | 1.94 | 2.05 | 2.02 | 2.05 |
| plating undercoat film | | | | | |
| [mgKOH/g] | | | | | |
| Surface roughness Rz_{JIS} | 0.23 | 0.40 | 0.20 | 0.22 | 0.22 |
| of the surface of the electroless | | | | | |
| plating undercoat film | | | | | |
| (Surface roughness Rz_{JIS} | | | | | |
| of the electroless | | | | | |
| plating layer) [μm] | | | | | |
| Adhesiveness before plating | ◯ | ◯ | ◯ | ◯ | ◯ |
| Adhesiveness after plating | ◯ | ◯ | ◯ | ◯ | ◯ |
| Heat resistance | ◯ | ◯ | — | — | — |
| Heat resistance 2 | — | — | ◯ | ◯ | ◯ |

### INDUSTRIAL APPLICABILITY

The electroless plating undercoat film of the invention can be used as an undercoat of an electroless plating layer.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. An electroless plating undercoat film comprising (A) a conductive polymer and further comprising (B) a reactant of a polyol resin having an acid value and a polyisocyanate compound, wherein the acid value is 0.1 mgKOH/g to 30 mgKOH/g.

2. The electroless plating undercoat film according to claim 1, wherein the component (B) comprises a polyester polyol resin having an acid value.

3. The electroless plating undercoat film according to claim 1, wherein the component (A) is a substituted or unsubstituted polyaniline.

4. The electroless plating undercoat film according to claim 1, or unsubstituted polyaniline is doped with a dopant.

5. The electroless plating undercoat film according to claim 4, wherein the dopant is an organic acid ion derived from sulfosuccinic acid derivative represented by the following formula (III): 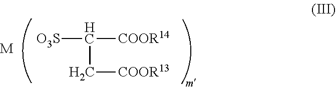
wherein in the formula (III), M is a hydrogen atom, an organic free radical, or an inorganic free radical; m′ is the valence of M; R¹³ and R¹⁴ are independently a hydrocarbon group or a —(R¹⁵O)ᵣ—R¹⁶) group; R¹⁵'s are independently a hydrocarbon group or a silylene group, R¹⁶ is a hydrogen atom, hydrocarbon group, or a R¹⁷₃Si— group, and r is an integer of 1 or more; R¹⁷'s are independently a hydrocarbon group.

6. The electroless plating undercoat film according to claim 4, wherein the dopant is sodium di-2-ethylhexyl sulfosuccinate.

7. A composition for forming an electroless plating undercoat film for forming the electroless plating undercoat film according to claim 1 comprising:
(A) a conductive polymer,
(C) a polyol resin having an acid value, and
(D) a polyisocyanate compound.

8. The composition for forming an electroless plating undercoat film according to claim 7, wherein the total ratio of the component (C) and the component (D) to non-volatile components in the composition for forming an electroless plating undercoat film is 10 to 90% by mass.

9. The composition for forming an electroless plating undercoat film according to claim 7, wherein the molar ratio of the isocyanate group in the component (D) to the hydroxyl group in the component (C) is 0.6 to 10.

10. The composition for forming an electroless plating undercoat film according to claim 7, further comprising (E) a polyol resin having no acid value.

11. The composition for forming an electroless plating undercoat film according to claim 10, wherein the component (E) comprises one or more selected from the group consisting of a polyester polyol resin having no acid value and a polyether polyol resin having no acid value.

12. The composition for forming an electroless plating undercoat film according to claim 10, wherein the total ratio of the component (C), the component (D), and the component (E) to non-volatile components in the composition for forming an electroless plating undercoat film is 10 to 90% by mass.

13. The composition for forming an electroless plating undercoat film according to claim 10, wherein the molar ratio of the isocyanate group in the component (D) to the sum of the hydroxyl group in the component (C) and the hydroxyl group in the component (E) is 0.6 to 10.

14. The composition for forming an electroless plating undercoat film according to claim 7, wherein the component (D) is a blocked polyisocyanate compound.

15. The composition for forming an electroless plating undercoat film according to claim 7, further comprising a solvent.

16. A plating laminate comprising a substrate,
the electroless plating undercoat film according to claim 1, and
an electroless plating layer comprising a metal,
wherein the electroless plating layer and the electroless plating undercoat film is in contact with each other.

17. The plating laminate according to claim 16, wherein the metal is copper.

18. The plating laminate according to claim 16, wherein the substrate is composed of a resin.

19. The plating laminate according to claim 18, wherein the substrate is composed of a polycarbonate resin, a polyester resin, a polyimide resin, a syndiotactic polystyrene resin, a liquid crystal polymer resin, or a polyphenylene sulfide resin.

20. A method of manufacturing a plating laminate comprising a step of: (i) forming an electroless plating undercoat film on a base material using the composition for forming an electroless plating undercoat film according to claim 7, and
(ii) forming an electroless plating layer comprising a metal on the electroless plating undercoat film.

21. The method for manufacturing a plating laminate according to claim 20, wherein in the step (ii), palladium is supported on the electroless plating undercoat film, and the electroless plating undercoat film supporting palladium is contacted with an electroless plating solution to form the electroless plating layer.

22. The method of manufacturing a plating laminate according to claim 21, wherein the supporting of palladium on the electroless plating undercoat film is performed by bringing a palladium chloride solution into contact with the electroless plating undercoat film.

23. The method for manufacturing a plating laminate according to claim 21, wherein the electroless plating solution comprises one or more metals selected from the group consisting of copper, nickel, gold, palladium, silver, tin, cobalt, and platinum.
